(19) United States
(12) Patent Application Publication
(10) Pub. No.: US 2023/0369146 A1
(43) Pub. Date: Nov. 16, 2023

(54) TEST STRUCTURE AND METHODS OF FORMING THE SAME

(71) Applicant: TAIWAN SEMICONDUCTOR MANUFACTURING COMPANY, LTD., Hsinchu (TW)

(72) Inventors: Yen-Ning CHEN, Kaohsiung (TW); CHIH TING YEH, Tainan (TW); Wen Han HUNG, Tainan (TW); Mao-Chia WANG, Tainan (TW)

(21) Appl. No.: 17/744,740

(22) Filed: May 16, 2022

(51) Int. Cl. H01L 21/66; H01L 21/027

(52) U.S. Cl. CPC H01L 22/34; H01L 22/12; H01L 21/0274

(57) ABSTRACT

A test structure and methods of forming the same are described. In some embodiments, the structure includes a first portion having a first thickness, and the first portion comprises one or more dielectric layers. The test structure further includes a second portion disposed adjacent the first portion, the second portion has a second thickness substantially less than the first thickness, and the second portion includes the one or more dielectric layers and a first plurality of test conductive features disposed in the one or more dielectric layers. The test structure further includes a third portion disposed adjacent the second portion, the third portion has a third thickness substantially less than the second thickness, and the third portion comprises the one or more dielectric layers and a second plurality of test conductive features disposed in the one or more dielectric layers.

### BACKGROUND

Over the history of the semiconductor industry, the minimum features sizes of components within an integrated chip have generally decreased. Smaller minimum features sizes have largely been achieved by improving a resolution of photolithography tools used to print such features. However, as the resolution of a photolithography tool improves, the depth of focus of the electromagnetic radiation generated by the photolithography tool decreases. It has been appreciated that as the depth of focus decreases, a process window of a photolithography tool shrinks. If the exposure of a photoresist layer goes outside of the process window of a photolithography tool, sections of the photoresist layer may not be sufficiently exposed and a corresponding feature may not be properly printed. This can lead to yield lost and/or integrated chip failure. Therefore, an improved structure and method to improve the depth of focus of a photolithography tool.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a schematic view of a lithography system, in accordance with some embodiments.

FIG. 2A is a perspective view of one of various stages of manufacturing a semiconductor device structure, in accordance with some embodiments.

FIG. 2B is a cross-sectional side view of the stage of manufacturing the semiconductor device structure taken along line A-A of FIG. 2A, in accordance with some embodiments.

FIG. 3 is a cross-sectional side view of a stage of manufacturing the semiconductor device structure, in accordance with some embodiments.

FIG. 4 is a cross-sectional side view of a stage of manufacturing the semiconductor device structure, in accordance with some embodiments.

FIGS. 5A-5C are cross-sectional side views of various stages of manufacturing a test structure in the semiconductor device structure, in accordance with some embodiments.

FIGS. 6A-6D are top views of the test structure, in accordance with some embodiments.

FIG. 7 is a top view of a substrate, in accordance with some embodiments.

FIG. 8 is a flow chart showing a method for adjusting a focus of a light in a lithography system, in accordance with some embodiments.

FIG. 9 is a cross-sectional side view of a stage of manufacturing the semiconductor device structure, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “over,” “on,” “top,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

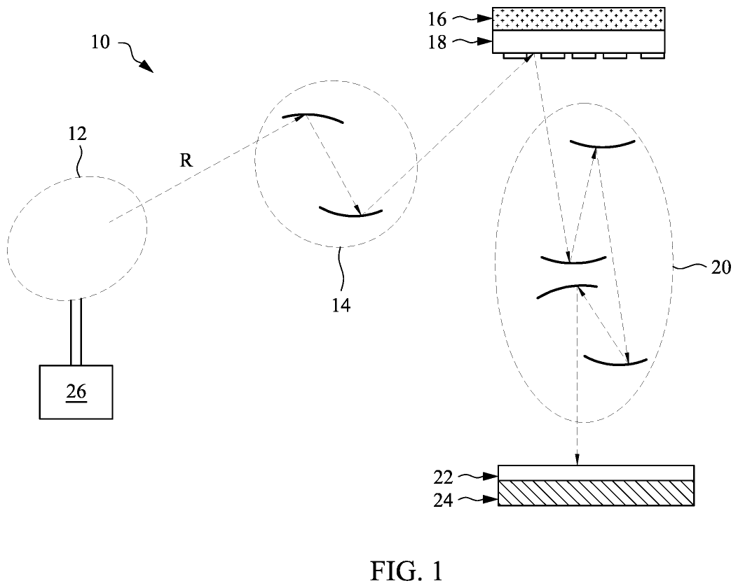

FIG. 1 is a schematic view diagram of a lithography system 10, in accordance with some embodiments. The lithography system 10 may be generically referred to as a scanner that is configured to perform lithography exposure processes with respective radiation source and exposure mode. In some embodiments, the lithography system 10 is an extreme ultraviolet lithography (EUVL) system. For example, the lithography system may be designed to expose a photoresist layer by EUV light or EUV radiation. The photoresist layer is a material sensitive to the EUV light. The lithography system 10 employs a radiation source 12 to generate light, such as EUV light having a wavelength ranging between about 1 nm and about 100 nm. In one example, the radiation source 12 generates an EUV light with a wavelength centered at about 13.5 nm. Accordingly, the radiation source 12 may be an EUV radiation source 12.

The lithography system 10 also employs an illuminator 14. In various embodiments, the illuminator 14 includes various refractive optic components, such as a single lens or a lens system having multiple lenses (zone plates) or alternatively reflective optics (for EUV lithography system), such as a single mirror or a mirror system having multiple mirrors, in order to direct light from the radiation source 12 onto a mask stage 16, particularly to a mask 18 provided on the mask stage 16. In the present embodiment where the radiation source 12 generates light in the EUV wavelength range, the illuminator 14 employs reflective optics. In some embodiments, the illuminator 14 includes a dipole illumination component.

In some embodiments, the illuminator 14 is operable to configure the mirrors to provide a proper illumination to the mask 18. In one example, the mirrors of the illuminator 14 are switchable to reflect EUV light to different illumination positions. In some embodiments, a stage prior to the illuminator 14 may additionally include other switchable mirrors that are controllable to direct the EUV light to different illumination positions with the mirrors of the illuminator 14. In some embodiments, the illuminator 14 is configured to provide an on-axis illumination (ONI) to the mask 18. In an example, a disk illuminator 14 with partial coherence of at most 0.3 is employed. In some other embodiments, the illuminator 14 is configured to provide an off-axis illumination (OAI) to the mask 18. In an example, the illuminator 14 is a dipole illuminator. The dipole illuminator has a partial coherence of at most 0.3 in some embodiments.

The mask stage 16 is configured to secure the mask 18. In some embodiments, the mask stage 16 includes an electrostatic chuck (e-chuck) to secure the mask 18. This is because gas molecules absorb EUV light, and the lithography system for the EUVL patterning is maintained in a vacuum environment to avoid the EUV intensity loss. In the disclosure, the terms of mask, photomask, and reticle are used interchangeably to refer to the same item.

The lithography system 10 may include a projection optics module (or projection optics box (POB) 20 for imaging the pattern of the mask 18 on to a substrate 22 secured on a substrate stage 24 of the lithography system 10. The POB 20 has refractive optics (such as for UV lithography system) or alternatively reflective optics (such as for EUV lithography system) in various embodiments. The light directed from the mask 18, diffracted into various diffraction orders and carrying the image of the pattern defined on the mask 18, is collected by the POB 20. The POB 20 may include a magnification of less than one (thereby the size of the “image” on a target (such as the substrate 22 discussed below) is smaller than the size of the corresponding “object” on the mask 18). The illuminator 14 and the POB 20 are collectively referred to as an optical module of the lithography system 10.

As discussed above, the lithography system 10 also includes the substrate stage 24 to secure the substrate 22 to be patterned. In the present embodiment, the substrate 22 may be a semiconductor wafer. For example, the substrate 22 may be made of silicon or another semiconductor material. Alternatively or additionally, the substrate 22 may include other elementary semiconductor materials such as germanium (Ge). In some embodiments, the substrate 22 is made of a compound semiconductor such as silicon carbide (SiC), gallium arsenic (GaAs), indium arsenide (InAs), or indium phosphide (InP). In some embodiments, the substrate 22 is made of an alloy semiconductor such as silicon germanium (SiGe), silicon germanium carbide (SiGeC), gallium arsenic phosphide (GaAsP), or gallium indium phosphide (GaInP). In some other embodiments, the substrate 22 may be a silicon-on-insulator (SOI) or a germanium-on-insulator (GOI) substrate.

In addition, the substrate 22 may have various device elements. Examples of device elements that are formed in the substrate 22 include transistors (e.g., metal oxide semiconductor field effect transistors (MOSFET), complementary metal oxide semiconductor (CMOS) transistors, bipolar junction transistors (BJT), high voltage transistors, high-frequency transistors, p-channel and/or n-channel field-effect transistors (PFETs/NFETs), etc.), diodes, and/or other applicable elements. Various processes are performed to form the device elements, such as deposition, etching, implantation, photolithography, annealing, and/or other suitable processes. In some embodiments, the substrate 22 is coated with a resist layer sensitive to the EUV light in the present embodiment. Various components including those described above are integrated together and are operable to perform lithography exposing processes.

The lithography system 10 may further include other modules or be integrated with (or be coupled with) other modules.

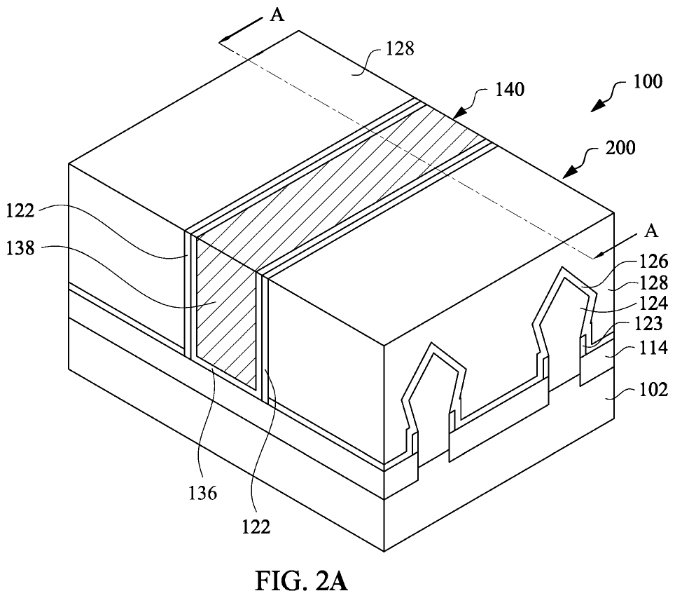

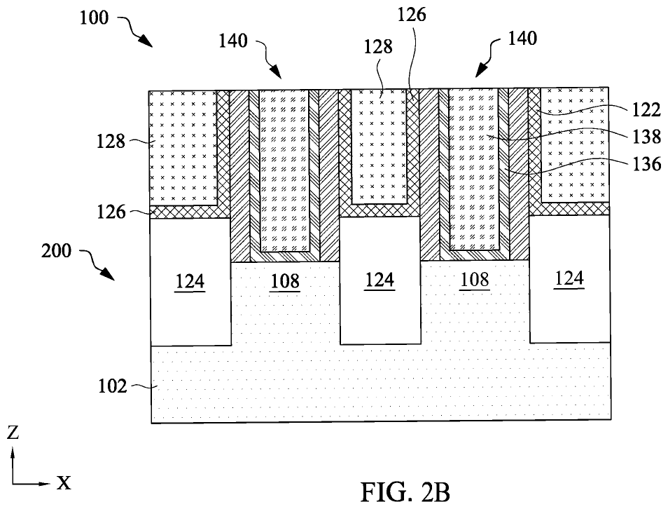

FIGS. 2A and 2B illustrate a stage of manufacturing a semiconductor device structure 100. As shown in FIGS. 2A and 2B, the semiconductor device structure 100 includes a substrate 102 and one or more device elements 200 formed on the substrate 102. The substrate 102 may be the substrate 22 shown in FIG. 1. The substrate 102 may be a semiconductor substrate. In some embodiments, the substrate 102 includes a single crystalline semiconductor layer on at least the surface of the substrate 102. The substrate 102 may include a crystalline semiconductor material such as, but not limited to silicon (Si), germanium (Ge), silicon germanium (SiGe), gallium arsenide (GaAs), indium antimonide (InSb), gallium phosphide (GaP), gallium antimonide (GaSb), indium aluminum arsenide (InAlAs), indium gallium arsenide (InGaAs), gallium antimony phosphide (GaSbP), gallium arsenic antimonide (GaAsSb), and indium phosphide (InP). For example, the substrate 102 is made of Si. In some embodiments, the substrate 102 is a silicon-on-insulator (SOI) substrate, which includes an insulating layer (not shown) disposed between two silicon layers. In one aspect, the insulating layer is an oxygen-containing material, such as an oxide.

The substrate 102 may include one or more buffer layers (not shown) on the surface of the substrate 102. The buffer layers can serve to gradually change the lattice constant from that of the substrate to that of the source/drain regions. The buffer layers may be formed from epitaxially grown crystalline semiconductor materials such as, but not limited to Si, Ge, germanium tin (GeSn), SiGe, GaAs, InSb, GaP, GaSb, InAlAs, InGaAs, GaSbP, GaAsSb, GaN, GaP, and InP.

The substrate 102 may include various regions that have been suitably doped with impurities (e.g., p-type or n-type impurities). The dopants are, for example phosphorus for an n-type fin field effect transistor (FinFET) and boron for a p-type FinFET.

As described above, the device elements 200 may be any suitable devices, such as transistors, diodes, imaging sensors, resistors, capacitors, inductors, memory cells, or a combination thereof. In some embodiments, the device elements 200 are transistors, such as planar field effect transistors (FETs), FinFETs, nano structure transistors, or other suitable transistors. The nanostructure transistors may include nanosheet transistors, nanowire transistors, gate-all-around (GAA) transistors, multi-bridge channel (MBC) transistors, or any transistors having the gate electrode surrounding the channels. An example of the device elements 200 formed on the substrate 102 is a FinFET, which is shown in FIGS. 2A and 2B. The device elements 200 include source/drain (S/D) regions 124 and gate stacks 140 (only one is shown in FIG. 2A). Each gate stack 140 may be disposed between S/D regions 124 serving as source regions and S/D regions 124 serving as drain regions. For example, each gate stack 140 may extend along the Y-axis between one or more S/D regions 124 serving as source regions and one or more S/D regions 124 serving as drain regions. As shown in FIG. 2B, two gate stacks 140 are formed on the substrate 102. In some embodiments, more than two gate stacks 140 are formed on the substrate 102. Channel regions 108 are formed between S/D regions 124 serving as source regions and S/D regions 124 serving as drain regions.

The S/D regions 124 may include a semiconductor material, such as Si or Ge, a III-V compound semiconductor, a II-VI compound semiconductor, or other suitable semiconductor material. Exemplary S/D region 124 may include, but are not limited to, Ge, SiGe, GaAs, AlGaAs, GaAsP, SiP, InAs, AlAs, InP, GaN, InGaAs, InAlAs, GaSb, AlP, GaP, and the like. The S/D regions 124 may include p-type dopants, such as boron; n-type dopants, such as phosphorus or arsenic; and/or other suitable dopants including combinations thereof. The S/D regions 124 may be formed by an epitaxial growth method using CVD, atomic layer deposition (ALD) or molecular beam epitaxy (MBE). The channel regions 108 may include one or more semiconductor materials, such as Si, Ge, GeSn, SiGe, GaAs, InSb, GaP, GaSb, InAlAs, InGaAs, GaSbP, GaAsSb, GaN, GaP, or InP. In some embodiments, the channel regions 108 include the same semiconductor material as the substrate 102. In some embodiments, the device elements 200 are FinFETs, and the channel regions 108 are a plurality of fins disposed below the gate stacks 140. In some embodiments, the device elements 200 are nanostructure transistors, and the channel regions 108 are surrounded by the gate stacks 140.

As shown in FIGS. 2A and 2B, each gate stack 140 includes a gate electrode layer 138 disposed over the channel region 108 (or surrounding the channel region 108 for nanostructure transistors). The gate electrode layer 138 may be a metal-containing material such as tungsten, cobalt, aluminum, ruthenium, copper, multilayers thereof, or the like, and can be deposited by ALD, plasma enhanced chemical vapor deposition (PECVD), MBD, physical vapor deposition (PVD), or any suitable deposition technique. Each gate stack 140 may further include a gate dielectric layer 136 disposed over the channel region 108. The gate electrode layer 138 may be disposed over the gate dielectric layer 136. In some embodiments, an interfacial layer (not shown) may be disposed between the channel region 108 and the gate dielectric layer 136, and one or more work function layers (not shown) may be formed between the gate dielectric layer 136 and the gate electrode layer 138. The interfacial dielectric layer may include a dielectric material, such as an oxygen-containing material or a nitrogen-containing material, or multilayers thereof, and may be formed by any suitable deposition method, such as CVD, PECVD, or ALD. The gate dielectric layer 136 may include a dielectric material such as an oxygen-containing material or a nitrogen-containing material, a high-k dielectric material having a k value greater than that of silicon dioxide, or multilayers thereof. The gate dielectric layer 136 may be formed by any suitable method, such as CVD, PECVD, or ALD. In some embodiments, the gate dielectric layer 136 may be a conformal layer. The term “conformal” may be used herein for ease of description upon a layer having substantial same thickness over various regions. The one or more work function layers may include aluminum titanium carbide, aluminum titanium oxide, aluminum titanium nitride, or the like.

Gate spacers 122 are formed along sidewalls of the gate stacks 140 (e.g., sidewalls of the gate dielectric layers 136). The gate spacers 122 may include silicon oxycarbide, silicon nitride, silicon oxynitride, silicon carbon nitride, the like, multi-layers thereof, or a combination thereof, and may be deposited by CVD, ALD, or other suitable deposition technique.

As shown in FIG. 2A, fin sidewall spacers 123 may be disposed on opposite sides of each S/D region 124, and the fin sidewall spacers 123 may include the same material as the gate spacers 122. Portions of the gate stacks 140, the gate spacers 122, and the fin sidewall spacers 123 may be disposed on isolation regions 114. The isolation regions 114 are disposed on the substrate 102. The isolation regions 114 may include an insulating material such as an oxygen-containing material, a nitrogen-containing material, or a combination thereof. In some embodiments, the isolation regions 114 are shallow trench isolation (STI). The insulating material may be formed by a high-density plasma chemical vapor deposition (HDP-CVD), a flowable chemical vapor deposition (FCVD), or other suitable deposition process. In one aspect, the isolation regions 114 includes silicon oxide that is formed by a FCVD process.

As shown in FIGS. 2A and 2B, a contact etch stop layer (CESL) 126 is formed on the S/D regions 124 and the isolation region 114, and an interlayer dielectric (ILD) layer 128 is formed on the CESL 126. The CESL 126 can provide a mechanism to stop an etch process when forming openings in the ILD layer 128. The CESL 126 may be conformally deposited on surfaces of the S/D regions 124 and the isolation regions 114. The CESL 126 may include an oxygen-containing material or a nitrogen-containing material, such as silicon nitride, silicon carbon nitride, silicon oxynitride, carbon nitride, silicon oxide, silicon carbon oxide, or the like, or a combination thereof, and may be deposited by CVD, PECVD, ALD, or any suitable deposition technique. The ILD layer 128 may include an oxide formed by tetraethylorthosilicate (TEOS), un-doped silicate glass, or doped silicon oxide such as borophosphosilicate glass (BPSG), fused silica glass (FSG), phosphosilicate glass (PSG), boron doped silicon glass (BSG), organosilicate glass (OSG), SiOC, and/or any suitable low-k dielectric materials (e.g., a material having a dielectric constant lower than that of silicon dioxide), and may be deposited by spin-on, CVD, FCVD, PECVD, PVD, or any suitable deposition technique.

A conductive contact (not shown) may be disposed in the ILD layer 128 and over the S/D region 124. The conductive contact may be electrically conductive and include a material having one or more of Ru, Mo, Co, Ni. W, Ti, Ta, Cu, Al, TiN or TaN, and the conductive contact may be formed by any suitable method, such as electro-chemical plating (ECP), or PVD. A silicide layer (not shown) may be disposed between the conductive contact and the S/D region 124.

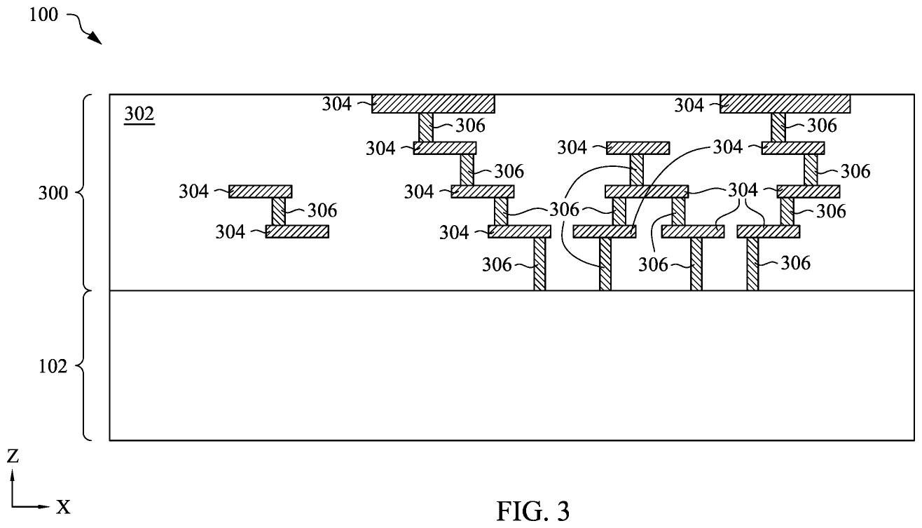

The semiconductor device structure 100 may further includes an interconnection structure 300 disposed over the device elements 200 and the substrate 102, as shown in FIG. 3. The interconnection structure 300 includes various conductive features, such as a first plurality of conductive features 304 and second plurality of conductive features 306, and an intermetal dielectric (IMD) layer 302 to separate and isolate various conductive features 304, 306. In some embodiments, the first plurality of conductive features 304 are conductive lines and the second plurality of conductive features 306 are conductive vias. The interconnection structure 300 includes multiple levels of the conductive features 304, and the conductive features 304 are arranged in each level to provide electrical paths to various device elements 200 disposed below. The conductive features 306 provide vertical electrical routing from the device elements 200 to the conductive features 304 and between conductive features 304. For example, the bottom-most conductive features 306 of the interconnection structure 300 may be electrically connected to the conductive contacts disposed over the S/D regions 124 (FIG. 2B) and the gate electrode layer 138 (FIG. 2B). The conductive features 304 and conductive features 306 may be made from one or more electrically conductive materials, such as metal, metal alloy, metal nitride, or silicide. For example, the conductive features 304 and the conductive features 306 are made from copper, aluminum, aluminum copper alloy, titanium, titanium nitride, tantalum, tantalum nitride, titanium silicon nitride, zirconium, gold, silver, cobalt, nickel, tungsten, tungsten nitride, tungsten silicon nitride, platinum, chromium, molybdenum, hafnium, other suitable conductive material, or a combination thereof. In some embodiments, barrier layers (not shown) and/or liners (not shown) may be formed between the conductive features 304, 306 and the IMD layer 302 to prevent metal diffusion from the conductive features 304, 306 into the IMD layer 302.

The IMD layer 302 includes one or more dielectric materials to provide isolation functions to various conductive features 304, 306. The IMD layers 302 may include multiple dielectric layers embedding multiple levels of conductive features 304, 306. The IMD layer 302 is made from a dielectric material, such as SiOₓ, SiOₓC_{y}H_{z}, or SiOₓC_{y}, where x, y and z are integers or non-integers. In some embodiments, the IMD layer 302 includes a dielectric material having a k value ranging from about 1 to about 5.

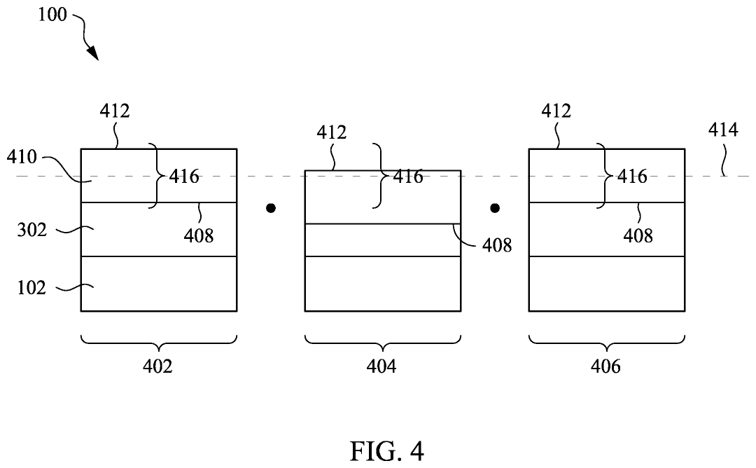

FIG. 4 is a cross-sectional side view of a stage of manufacturing the semiconductor device structure 100, in accordance with some embodiments. As shown in FIG. 4, the semiconductor device structure 100 includes the substrate 102, which may be a semiconductor wafer in some embodiments. The substrate 102 includes regions 402, 404, 406. In some embodiments, the region 404 is the center region of the substrate 102 and the regions 402, 406 are edge regions of the substrate 102. The regions 402, 404, 406 may be any regions of the substrate 102. The portions of the substrate 102 located between the regions 402 and 404 and between the regions 404 and 406 are omitted and represented by dots.

As shown in FIG. 4, the IMD layer 302 is disposed over the substrate 102 and over the device elements 200 (FIGS. 2A and 2B). The conductive features, such as the conductive features 304, 306 shown in FIGS. 2A and 2B disposed in the IMD layer 302 are omitted for clarity. The IMD layer 302 shown in FIG. 4 includes at least one level of conductive features. As shown in FIG. 4, a top surface 408 of the IMD layer 302 is non-planar after the planarization process to remove excess conductive material formed on the IMD layer 302 as a result of dishing effect. A photoresist layer 410 is formed on the IMD layer 302. Because of the non-planar top surface 408 of the IMD layer 302, the top surface 412 of the photoresist layer 410 is also non-planar. In other words, the total thickness of the materials formed on the substrate 102 in one region, such as the region 402, 404, or 406, is different from the total thickness of the materials formed on the substrate 102 in a different region, such as the region 402, 404, or 406.

Next, the semiconductor device structure 100 is placed in a lithography system, such as the lithography system 10 shown in FIG. 1. The photoresist layer 410 is selectively exposed to light, such as EUV light, generated by the lithography system to modify a solubility of an exposed region and define a soluble region having a pattern corresponding to a photomask, such as the mask 18 shown in FIG. 1. During the exposure, the light is focused on an image plane 414 located at a vertical position along the z-axis. The light focused on the image plane 414 has a depth of focus 416 (i.e., a distance extending in opposite directions from the image plane 414 within which a projected image has acceptable optical properties, such as focus, dose, etc., to expose the photoresist layer 410). Due to the non-planar top surface 412 of the photoresist layer 410, the depth of focus 416 does not cover the entire thickness of the photoresist layer 410 in some regions of the substrate 102. As shown in FIG. 4, portions of the photoresist layer 410 are outside of the depth of focus 416 in the region 404. As a result, sections of the photoresist layer 410 may not be sufficiently exposed and a corresponding feature may not be properly formed.

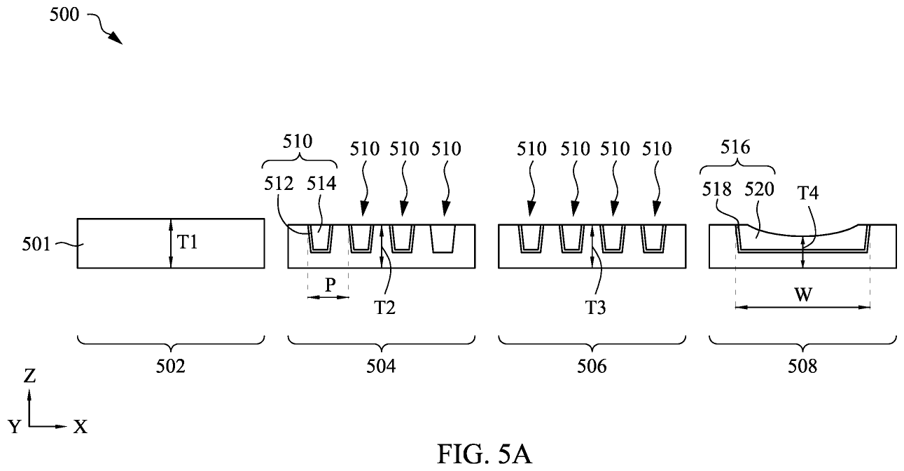

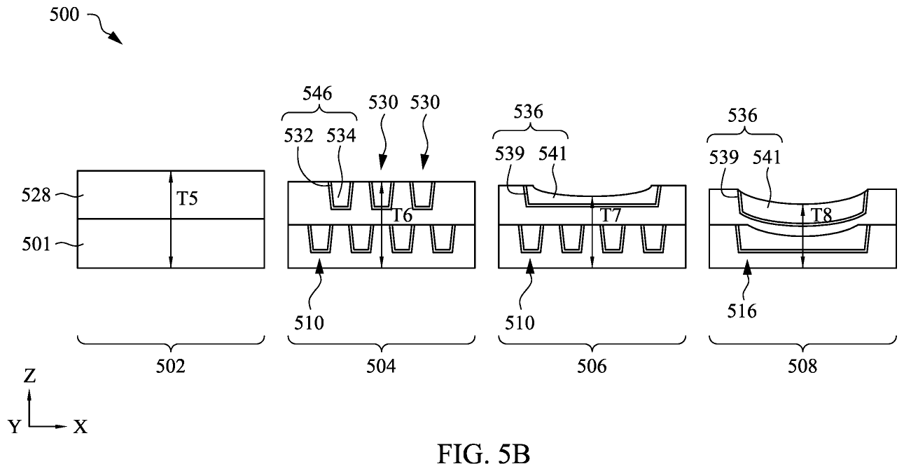

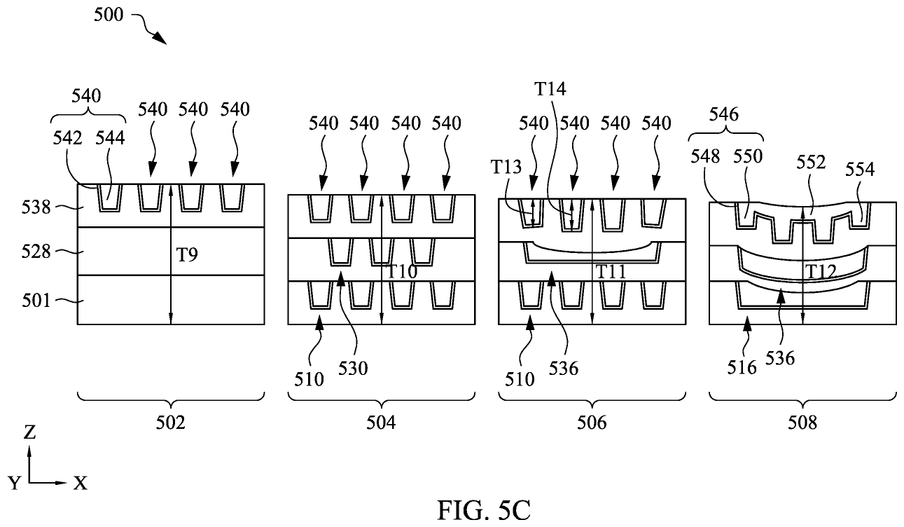

In order to determine how the focus of the light from the lithography system should be adjusted for processing subsequent substrates, a test structure 500 is formed over the substrate 102. FIGS. 5A to 5C are cross-sectional side views of various stages of manufacturing the test structure 500 in the semiconductor device structure 100, in accordance with some embodiments. As shown in FIG. 5A, a dielectric layer 501 is formed over the substrate 102 (FIG. 4). The dielectric layer 501 may be one layer of the IMD layer 302 shown in FIG. 3. In some embodiments, the dielectric layer 501 is formed on the IMD layer 302 shown in FIG. 4. The test structure 500 includes portions 502, 504, 506, and 508. In some embodiments, the portions 502, 504, 506, and 508 are disposed immediately adjacent one another. The dielectric layer 501 may be formed to cover the substrate 102, and a portion of the dielectric layer 501 forms the test structure 500, which is formed over a region of the substrate 102. Other portions of the dielectric layer 501 may be the IMD layer 302 having the conductive features 304 or conductive features 306 formed therein in other regions of the substrate 102.

As shown in FIG. 5A, test conductive features 510, 516 are formed in the dielectric layer 501 in portions 504, 506, 508 of the test structure 500. The test conductive feature 510 may include a barrier layer 512 and a conductive material 514 disposed on the barrier layer 512. The test conductive feature 516 may include a barrier layer 518 and a conductive material 520 disposed on the barrier layer 518. The test conductive features 510, 516 and the conductive features 304 (or conductive features 306) (FIG. 3) are formed simultaneously. For example, the dielectric layer 501 is formed over the substrate 102, portions of the dielectric layer 501 are in the test structure 500 and portions of the dielectric layer 501 are in the semiconductor device structure 100 (FIG. 3). Active conductive features, such as the conductive features 304, 306 (FIG. 3) and the test conductive features 510, 516 are formed simultaneously in the dielectric layer 501. In some embodiments, both test conductive features 510 and the conductive features 304 are formed in the dielectric layer 501, and the test conductive features 510 and the conductive features 304 are conductive lines.

The test conductive features 510, 516 include the same material as the conductive features 304. For example, the test conductive features 510, 516 are made from copper, aluminum, aluminum copper alloy, titanium, titanium nitride, tantalum, tantalum nitride, titanium silicon nitride, zirconium, gold, silver, cobalt, nickel, tungsten, tungsten nitride, tungsten silicon nitride, platinum, chromium, molybdenum, hafnium, other suitable conductive material, or a combination thereof. The barrier layers 512, 518 may be made from a nitride, such as titanium nitride or tantalum nitride. The size of the test conductive features 510 may be the same as the size of the conductive features 304.

As described above, the test conductive features 510 and the conductive features 304 are formed in the dielectric layer 501. The test conductive features 510 may have the same dimensions and pitch as the conductive features 304. In some embodiments, the pitch P of the test conductive features 510 is 64 nm, which is the same as the pitch of the conductive features 304. To form the test conductive features 510, 516 and the conductive features 304 in the dielectric layer 501, openings (not shown) are first formed in the dielectric layer 501, and the openings are filled with the test conductive features 510, 516 and the conductive features 304. The conductive material of the test conductive features 510, 516 and the conductive features 304 is also formed on the dielectric layer 501, and a planarization process, such as a chemical-mechanical polishing (CMP) process, is performed to remove the conductive material formed on the dielectric layer 501. The CMP process can cause dishing effect when performed on two different materials, such as the dielectric material of the dielectric layer 501 and the conductive material (e.g. metal) of the test conductive features 510, 516 and the conductive features 304. The larger the dimensions of the conductive material formed in the dielectric layer 501, the worse the dishing effect. In some embodiments, the test conductive feature 516 has a width W that is about 3 times to about 10 times the pitch P of the test conductive features 510. In some embodiments, the width W is about 3 times to about 5 times the pitch P. In some embodiments, the width W is about 8 times to about 10 times the pitch P. The test conductive feature 516 may have a substantially square cross-section in the x-y plane. The dimensions of the test conductive feature 516 are substantially greater than the dimensions of the test conductive feature 510.

As shown in FIG. 5A, the portion 502 of the test structure 500 has a thickness T1, the portion 504 has a thickness T2, the portion 506 has a thickness T3, and the portion 508 has a thickness T4. There are no test conductive features 510 formed in the portion 502. Because the test conductive features 510 are formed in the dielectric layer 501 in the portions 504, 506, the thicknesses T2 and T3 are substantially less than the thickness T1. In some embodiments, the number of test conductive features 510 formed in the portion 504 is the same as the number of test conductive features 510 formed in the portion 506, and the thickness T2 is substantially the same as the thickness T3. The number of the test conductive features 510 formed in the dielectric layer 501 in the portion 504 or 506 may range from about 2 to about 10. If the number of the test conductive feature 510 in the portion 504 or 506 is less than 2, the dishing effect may not be strong enough to create a difference between the thickness T1 and the thickness T2 (or between the thickness T1 and the thickness T3). On the other hand, if the number of the test conductive features 510 in the portion 504 or 506 is greater than 10, the dishing effect may be too strong, and there may not be enough difference between the thickness T2 and the thickness T4 (or between the thickness T3 and the thickness T4). The thickness T4 is substantially less than the thickness T2 or thickness T3 due to the dishing effect caused by the test conductive feature 516, which is substantially larger than the dimensions of the test conductive feature 510. The differences in thicknesses among the portions 502, 504, 506, 508 are the result of the CMP process performed on the portions 502, 504, 506, 508. Because the numbers and dimensions of the test conductive features 510, 516 are known, the thicknesses T1, T2, T3, T4 as the result of the CMP process can be determined. In other words, the differences among the thicknesses T1, T2, T3, T4 can be determined. In some embodiments, the dielectric layer 501 is the first IMD layer 302 formed on the device elements 200 (FIG. 2A). For example, the top surface of the ILD layer 128 (FIG. 2A) may be substantially planar, and the dielectric layer 501 is formed on the ILD layer 128.

As shown in FIG. 5B, a dielectric layer 528 is formed on the dielectric layer 501, and test conductive features 530, 536 are formed in the dielectric layer 528. The test conductive feature 530 includes a barrier layer 532 and a conductive material 534 disposed on the barrier layer 532. The barrier layer 532 may include the same material as the barrier layer 512, and the conductive material 534 may include the same material as the conductive material 514. The test conductive feature 536 includes a barrier layer 539 and a conductive material 541 disposed on the barrier layer 539. The barrier layer 539 may include the same material as the barrier layer 518, and the conductive material 541 may include the same material as the conductive material 520. The dielectric layer 528 and the test conductive features 530, 536 may be formed by the same processes as the dielectric layer 501 and the test conductive features 510, 516. The test conductive features 530 may have the same dimensions as the test conductive features 510, and the test conductive features 536 may have the same dimensions as the test conductive features 516. Similar to the dielectric layer 501, conductive features 306 (or conductive features 304) (FIG. 3) may be formed in the dielectric layer 528 in other regions of the substrate 102. In some embodiments, the test conductive features 530 disposed in the dielectric layer 528 and the test conductive features 510 disposed in the dielectric layer 501 are offset, such that the test conductive feature 530 is disposed over the space between adjacent test conductive features 510.

As described above, the dishing effect can lead to different thicknesses based on different amounts of the conductive material in the dielectric layer 528. As shown in FIG. 5B, the dimensions of the test conductive features 530 and the test conductive features 536 are known, so the thickness of the dielectric layer 528 in different portions 502, 504, 506, 508 can be determined. Because the thicknesses T1, T2, T3, T4 (FIG. 5A) are known, the thickness T5 of the portion 502, the thickness T6 of the portion 504, the thickness T7 of the portion 506, and the thickness T8 of the portion 508 can be determined. The differences among the thicknesses T5, T6, T7, T8 can be determined. In some embodiments, the thickness T5 is substantially greater than the thickness T6, which is substantially greater than the thickness T7, which is substantially greater than the thickness T8.

As shown in FIG. 5C, a dielectric layer 538 is formed on the dielectric layer 528, and test conductive features 540, 546 are formed in the dielectric layer 538. The test conductive feature 540 includes a barrier layer 542 and a conductive material 544 disposed on the barrier layer 542. The barrier layer 542 may include the same material as the barrier layer 512, and the conductive material 544 may include the same material as the conductive material 514. The test conductive feature 546 includes a barrier layer 548 and a conductive material 550 disposed on the barrier layer 548. The barrier layer 548 may include the same material as the barrier layer 518, and the conductive material 550 may include the same material as the conductive material 520. The test conductive features 540 may have the same dimensions as the test conductive features 510. The dielectric layer 538 and the test conductive features 540, 546 may be formed by the same processes as the dielectric layer 501 and the test conductive features 510, 516. In some embodiments, as shown in FIG. 5C, the test conductive features 540 formed in the portion 506 over the test conductive feature 536 may have different thicknesses. The test conductive features 540 disposed over the edge portion of the test conductive feature 536 may have a thickness T13, which may be substantially less than a thickness T14 of the test conductive features 540 disposed over the center portion of the test conductive feature 536. The dishing effect on the test conductive feature 536 leads to the different thicknesses of the test conductive features 540 disposed over the test conductive feature 536. Furthermore, as a result of the dishing effect on the test conductive features 516, 536 in the portion 508, the conductive material 550 of the test conductive feature 546 includes a top portion 552 and bottom portions 554 extending downward from the top portion 552. The top portion 552 is supposedly disposed over the dielectric layer 538 and to be removed by the CMP process. However, because the dishing effect on the test conductive features 516, 536 in the portion 508, the top portion 552 is disposed in the dielectric layer 538 and is not removed by the CMP process. As shown in FIG. 5C, in some embodiments, due to the dishing effect on the test conductive features 516, 536 in the portion 508, the test conductive features 546 disposed over the center portion of the test conductive feature 536 extend to a level below bottoms of the test conductive features 546 disposed over the edge portion of the test conductive feature 536.

Similar to the dielectric layers 501 and 528, conductive features 304 (or conductive features 306) (FIG. 3) may be formed in the dielectric layer 538 in other regions of the substrate 102. In some embodiments, the test conductive features 540 disposed in the dielectric layer 538 and the test conductive features 530 disposed in the dielectric layer 528 are offset, such that the test conductive feature 540 is disposed over the space between adjacent test conductive features 530.

As described above, the dishing effect can lead to different thicknesses based on different amounts of the conductive material in the dielectric layer 538. As shown in FIG. 5C, the dimensions of the test conductive features 540 and the test conductive features 546 are known, so the thickness of the dielectric layer 538 in different portions 502, 504, 506, 508 can be determined. Because the thicknesses T5, T6, T7, T8 (FIG. 5B) are known, the thickness T9 of the portion 502, the thickness T10 of the portion 504, the thickness T11 of the portion 506, and the thickness T12 of the portion 508 can be determined. The differences among the thicknesses T9, T10, T11, T12 can be determined. In some embodiments, the thickness T9 is substantially greater than the thickness T10, which is substantially greater than the thickness T11, which is substantially greater than the thickness T12.

FIGS. 5A to 5C illustrate various stages of manufacturing the test structure 500, which can be utilized to adjust the focus of a light in a lithography process. In some embodiments, the test structure 500 includes 4 portions 502, 504, 506, 508 having different thicknesses T9, T10, T11, T12, respectively. The number of portions having different thicknesses is not limited to 4. For example, the test structure 500 may include 2 to 10 portions having different thicknesses. The differences in the thicknesses are known because the test structure 500 is designed to create the differences in the thickness by using different amounts of conductive materials in the different portions of the test structure 500. Thus, if the number of portions having different thicknesses is less than 2, the test structure 500 would not have any portions having different thicknesses. On the other hand, if the number of portions having different thicknesses is greater than 10, the manufacturing cost is increased without significant advantage.

In some embodiments, each portion 502, 504, 506, 508 includes 3 dielectric layers 501, 528, 538, and different amounts of conductive material, such as the test conductive features 510, 516, 530, 536, 540, 546 are formed in different portions 502, 504, 506, 508 in one or more dielectric layers 501, 528, 538, as shown in FIGS. 5A to 5C. The dielectric layers 501, 528, 538 may be the IMD layer 302 (FIG. 3) in other regions of the interconnect structure 300 (FIG. 3). In other words, the interconnect structure 300 includes the test structure 500, and portions of the IMD layer 302 are part of the test structure 500, such as the dielectric layers 501, 528, 538. The number of dielectric layers is not limited to 3. For example, the test structure 500 may include 1 to 10 dielectric layers. If the number of dielectric layers is less than 1, there would not be the test structure 500. On the other hand, if the number of dielectric layers is greater than 10, the manufacturing cost is increased without significant advantage.

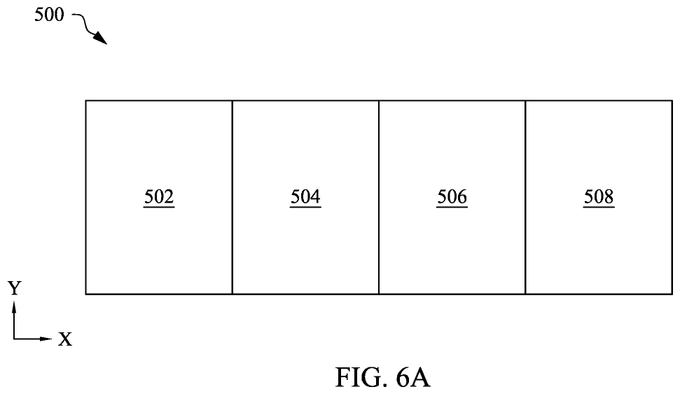

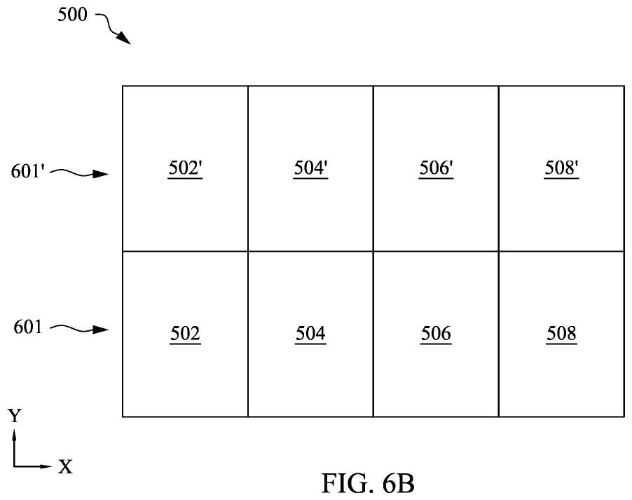

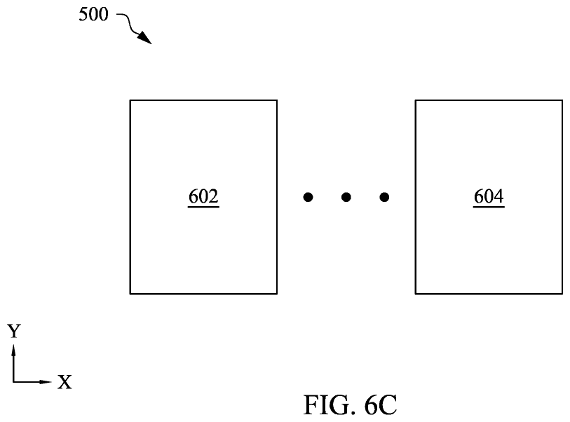

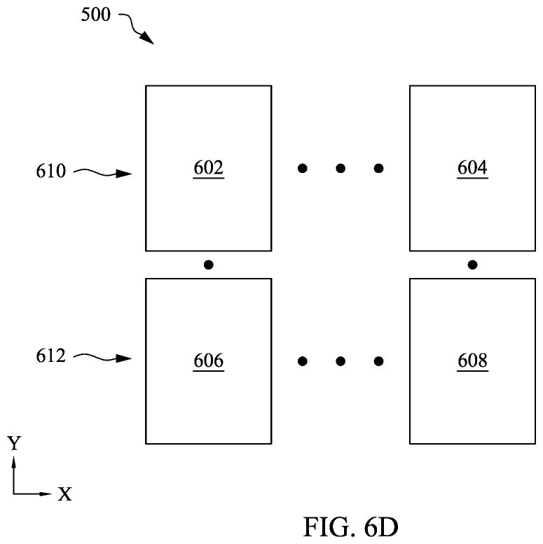

FIGS. 6A-6D are top views of the test structure 500, in accordance with some embodiments. In some embodiments, as shown in FIG. 6A, the test structure 500 includes portions 502, 504, 506, 508. The portions 502, 504, 506, 508 may be arranged so the thickness of the test structure 500 decreases (or increases) along the x-axis. For example, as described above, the portion 502 has the thickness T9, which is substantially greater than the thickness T10 of the portion 504, which is substantially greater than the thickness T11 of the portion 506, which is substantially greater than the thickness T12 of the portion 508. In some embodiments, as shown in FIG. 6B, the test structure 500 includes portions 502, 504, 506, 508 in a first row 601 and portions 502′, 504′, 506′, 508′ in a second row 601′. The portions 502′, 504′, 506′, 508′ may be identical to the portions 502, 504, 506, 508, with the exception that the test conductive features 516, 536, 546 (FIG. 5C) in portions 506, 508 and portions 506′, 508′ have different sizes. For example, the portion 506 includes the test conductive feature 536 (FIG. 5C) having a width along the x-axis that is about 3 times to about 5 times the pitch of the conductive features 304 (FIG. 3), and the portion 506′ includes the test conductive features 536 (FIG. 5C) having a width along the x-axis that is about 8 times to about 10 times the pitch of the conductive features 304 (FIG. 3). Similarly, the portion 508 includes the test conductive features 516, 536, 546 (FIG. 5C) each having a width along the x-axis that is about 3 times to about 5 times the pitch of the conductive features 304 (FIG. 3), and the portion 508′ includes the test conductive features 516, 536, 546 (FIG. 5C) each having a width along the x-axis that is about 8 times to about 10 times the pitch of the conductive features 304 (FIG. 3). The thickness of the test structure 500 decreases (or increases) in each row 601, 601′. For example, the thicknesses of the portions 502, 504, 506, 508 in row 601 decrease from the portion 502 to the portion 508. The thicknesses of the portions 502′, 504′, 506′, 508′ in row 601′ decrease from the portion 502′ to the portion 508′. The thickness of the portion 506′ may be substantially less than the thickness of the portion 506 due to the much larger test conductive feature 536 disposed in the portion 506′ than the test conductive feature 536 disposed in the portion 506. Similarly, the thickness of the portion 508′ may be substantially less than the thickness of the portion 508 due to the much larger test conductive features 516, 536, 546 disposed in the portion 508′ than the test conductive features 516, 536, 546 disposed in the portion 508.

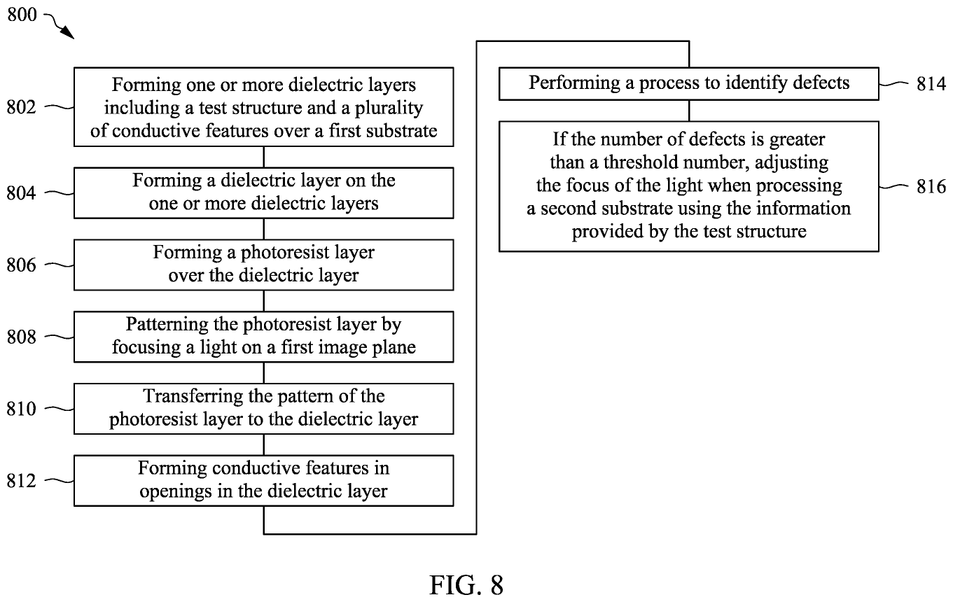

As shown in FIG. 6C, the test structure 500 includes at least two portions 602, 604 having different thicknesses. One or more portions, represented by dots, may or may not be disposed between the portions 602, 604. As shown in FIG. 6D, the test structure 500 may include a first row 610 having portions 602, 604 (and any portions between the portions 602, 604) and a second row 612 having portions 606, 608 (and any portions between the portions 606, 608). Additional rows, represented by dots, may be disposed between the rows 610, 612. As described above, each row includes portions having decreasing or increasing thicknesses. The decreasing or increasing thickness along x-axis helps to determine how to adjust the focus of the lithography tool, which is described in detail in FIG. 8.

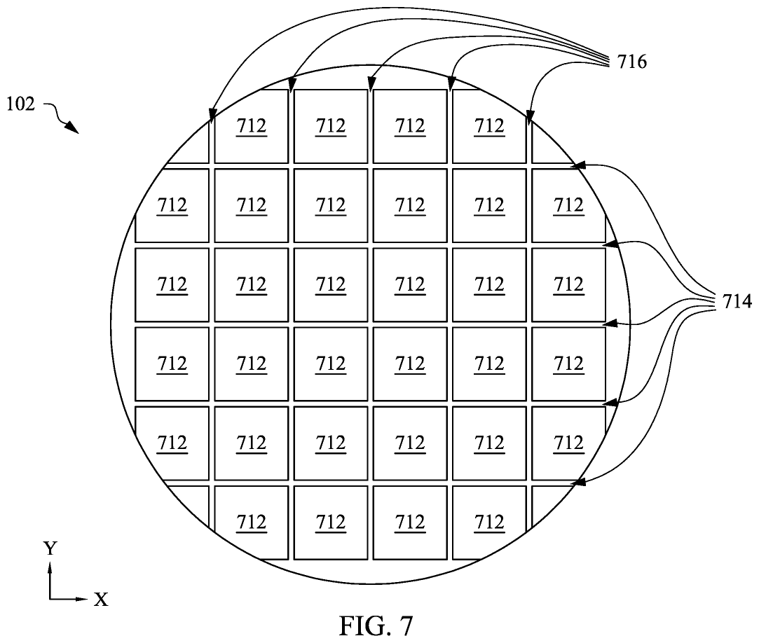

FIG. 7 is a top view of the substrate 102, in accordance with some embodiments. As shown in FIG. 7, the substrate 102 includes dies 712 and the adjoining scribe lines 714 and scribe lines 716, and the scribe lines 714 and scribe lines 716 separate the dies 712 from each other. Scribe lines 714 have longitudinal directions parallel to the x-axis, and the scribe lines 716 have longitudinal directions parallel to the y-axis, which is perpendicular to the x-axis. Each die 712 may include the semiconductor device structure 100 (FIG. 3). In some embodiments, one or more test structures 500 may be disposed in the scribe lines 714, 716. Because the test structures 500 are not active components and are formed to assist the adjustment of the focus of the lithography tool, the test structures 500 are formed in the scribe lines 714, 716, which may be eventually removed when separating the dies 712. However, the test structures 500 are not limited to be formed in the scribe lines 714, 176. In some embodiments, the test structures 500 are formed in the dies 712.

FIG. 8 is a flow chart showing a method 800 for adjusting a focus of a light in a lithography system, in accordance with some embodiments. The method 800 starts at operation 802, which is forming one or more dielectric layers over a first substrate. The one or more dielectric layers may be one or more dielectric layers 501, 528, 538 shown in FIG. 5C. A test structure and a plurality of conductive features are formed in the one or more dielectric layers. The test structure may be the test structure 500 shown in FIG. 5C, and the plurality of conductive features may be the conductive features 304, 306 shown in FIG. 3. In other words, the operation 802 may be the process of forming a portion of the interconnect structure 300 shown in FIG. 3, and the interconnect structure 300 includes the test structure 500 in addition to the conductive features 304, 306. In some embodiments, multiple test structures 500 are formed in the one or more dielectric layers.

At operation 804, a dielectric layer is formed on the one or more dielectric layers. The dielectric layer may be an IMD layer 302 as shown in FIG. 3, which is part of the interconnect structure 300. At this stage, the one or more dielectric layer and the dielectric layer formed thereon together may be the IMD layer 302 shown in FIG. 4. The top surface of the dielectric layer is non-planar, such as the non-planar top surface 408 shown in FIG. 4. The differences in thicknesses of portions of the dielectric layer disposed over the test structure 500 are known, because the test structure 500 is formed with the known thickness differences. The differences in thicknesses of portions of the dielectric layer disposed over other portions of the substrate 102 are not known. At operation 806, a photoresist layer is formed over the dielectric layer. The photoresist layer may be the photoresist layer 410 shown in FIG. 4. At operation 808, the photoresist layer is patterned by focusing a light on a first image plane. The photoresist layer may be patterned in the lithography system 10 shown in FIG. 1, and the first image plane may be the image plane 414 shown in FIG. 4. The patterning process may further include removing portions of the photoresist layer that are exposed to the light (or not exposed to the light) to form a plurality of openings in the photoresist layer. As described in FIG. 4, if the depth of focus is not covering the entire thickness of the photoresist layer, sections of the photoresist layer may not be sufficiently exposed and a corresponding feature may not be properly formed. For example, the openings formed in the photoresist layer may have a trapezoid shape.

At operation 810, the pattern of the photoresist layer is transferred to the dielectric layer disposed therebelow. As a result, a plurality of openings are formed in the dielectric layer. One or more openings in the dielectric layer may have a trapezoid shape as a result of trapezoid shape of the openings in the photoresist layer, and the portions of the dielectric layer defining the trapezoid shaped openings may collapse into the openings. At operation 812, conductive features are formed in the openings in the dielectric layer. The conductive features may be the conductive features 304 shown in FIG. 3. Some conductive features may not be properly formed due to the collapsed portions of the dielectric layer into the trapezoid shaped openings. At operation 814, a process is performed to identify defects, such as improperly formed conductive features. The process may be any suitable process that can identify pattern defects. In some embodiments, the process is to scan the surface to identify pattern defects. In some embodiments, the process is to measure electrical resistances of the conductive features. The defects may be located in active regions, such as in the dies 712 shown in FIG. 7. The defects may also be located in scribe lines, such as scribe lines 714, 716 shown in FIG. 7.

At operation 816, if the number of defects located in regions without the test structure is greater than a threshold number, the focus of the light in the lithography system is adjusted when processing a second substrate using the information provided by the test structure. For example, a plurality of defects are identified by the process, some of which are located over the test structure 500, and the rest are located in other regions without the test structure 500. In some embodiments, the threshold number may be 5, which means if the number of defects located in regions without the test structure 500 is greater than 5, the focus of the light in the lithography system will be adjusted when processing a second substrate. In some embodiments, identical processes may be performed on the first and second substrates. The differences in thicknesses in the portions of the one or more dielectric layers the test structure 500 is not formed therein and in the portions of the dielectric layer the test structure 500 is not formed thereunder are not known. Thus, an operator does not know how the image plane the light is focusing on should be adjusted. In order to determine how to adjust the focus of the light in the lithography system, the test structure 500 is utilized.

The test structure 500 formed in the one or more dielectric layers serves as a reference because the differences in thicknesses of portions of the test structure 500 are known, and the differences in thicknesses of the portions of the dielectric layer formed over the test structure 500 are also known. For example, referring back to FIG. 5C, if one or more defects are located in the dielectric layer over the portion 506 of the test structure 500, the difference between the thickness T9 and the thickness T11 is known. Thus, the image plane the light generated in the lithography system is focusing on should be lowered along the z-axis. In some embodiments, the image plane to be focused on is lowered by the difference between the thickness T9 and the thickness T11. For example, if the difference between the thickness T9 and the thickness T11 is about 10 nm, the image plane to be focused on is lowered along the z-axis by 10 nm. In some embodiments, the image plane to be focused on is lowered by a fraction of the difference between the thickness T9 and the thickness T11. For example, if the difference between the thickness T9 and the thickness T11 is about 10 nm, the image plane to be focused on is lowered along the z-axis by a fraction of 10 nm, such as 5 nm.

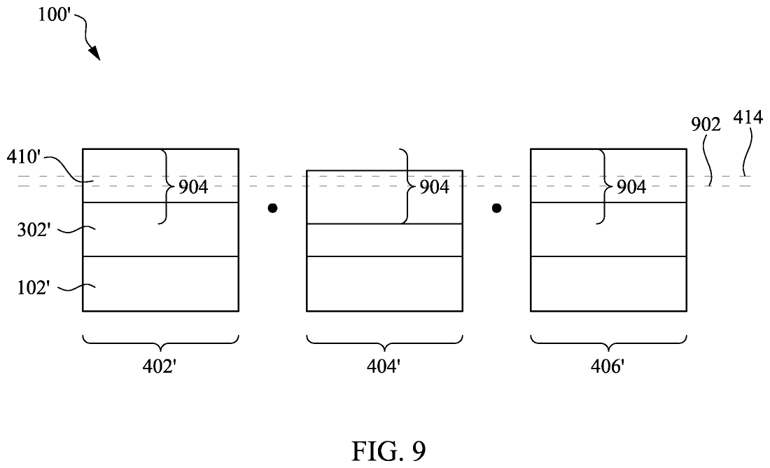

FIG. 9 is a cross-sectional side view of a stage of manufacturing the semiconductor device structure 100, in accordance with some embodiments. As shown in FIG. 9, the semiconductor device structure 100′ includes the substrate 102′, the IMD layer 302′ disposed over the substrate 102′, and the photoresist layer 410′ disposed over the IMD layer 302′. The substrate 102′ may be the same as the substrate 102, the photoresist layer 410′ may be the same as the photoresist layer 410, and the IMD layer 302′ may be the same IMD layer 302. In some embodiments, the test structure 500 is not formed in the IMD layer 302′. The semiconductor device structure 100′ is placed in the lithography system, such as the lithography system 10 shown in FIG. 1. The photoresist layer 410′ is selectively exposed to light, such as EUV light, generated by the lithography system to modify a solubility of an exposed region and define a soluble region having a pattern corresponding to a photomask, such as the mask 18 shown in FIG. 1. During the exposure, the light is focused on an image plane 902 located at a vertical position along the z-axis. The image plane 902 is lower on the z-axis compared to the image plane 414, which is shown in FIG. 9 for comparison purpose. The light focused on the image plane 902 has a depth of focus 904 (i.e., a distance extending in opposite directions from the image plane 902 within which a projected image has acceptable optical properties, such as focus, dose, etc., to expose the photoresist layer 410′). Unlike the depth of focus 416 shown in FIG. 4, the depth of focus 904 covers the entire thickness of the photoresist layer 410′ in all regions of the substrate 102′. As a result, defects, such as pattern defects, are reduced.

The present disclosure in various embodiments provides a test structure and methods of forming the same. In some embodiments, the test structure 500 includes portions having different thicknesses. Some embodiments may achieve advantages. For example, the test structures 500 are utilized to determine how much to adjust the image plane a light is to focus on in a lithography process in order to reduce defects.

An embodiment is a test structure. The structure includes a first portion having a first thickness, and the first portion comprises one or more dielectric layers. The test structure further includes a second portion disposed adjacent the first portion, the second portion has a second thickness substantially less than the first thickness, and the second portion includes the one or more dielectric layers and a first plurality of test conductive features disposed in the one or more dielectric layers. The test structure further includes a third portion disposed adjacent the second portion, the third portion has a third thickness substantially less than the second thickness, and the third portion comprises the one or more dielectric layers and a second plurality of test conductive features disposed in the one or more dielectric layers.

Another embodiment is a substrate. The substrate includes a plurality of dies, a plurality of scribe lines separating the plurality of dies, and at least one test structure disposed in a scribe line of the plurality of scribe lines. The test structure includes first portions arranged in a first row, the first portions have decreasing thicknesses along a first direction, and each portion of the first portions includes at least one dielectric layer and at least one test conductive feature disposed in the at least one dielectric layer.

A further embodiment is a method. The method includes forming one or more dielectric layers including a test structure and a plurality of conductive features over a first substrate, forming a dielectric layer on the one or more dielectric layers, forming a first photoresist layer over the dielectric layer, patterning the first photoresist layer by focusing a light on a first image plane, transferring a pattern of the first photoresist layer to the dielectric layer, forming conductive features in the dielectric layer, performing a process to identify defects, and patterning a second photoresist layer disposed over a second substrate by focusing the light on a second image plane different from the first image plane using information provided by the test structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A test structure disposed over a substrate, comprising:
a first portion having a first thickness, wherein the first portion comprises one or more dielectric layers;
a second portion disposed adjacent the first portion, wherein the second portion has a second thickness substantially less than the first thickness, and wherein the second portion comprises the one or more dielectric layers and a first plurality of test conductive features disposed in the one or more dielectric layers; and
a third portion disposed adjacent the second portion, wherein the third portion has a third thickness substantially less than the second thickness, and wherein the third portion comprises the one or more dielectric layers and a second plurality of test conductive features disposed in the one or more dielectric layers.

2. The test structure of claim 1, further comprising a fourth portion disposed adjacent the third portion, wherein the fourth portion has a fourth thickness substantially less than the third thickness, and wherein the fourth portion comprises the one or more dielectric layers and a third plurality of test conductive features disposed in the one or more dielectric layers.

3. The test structure of claim 2, wherein the one or more dielectric layers comprise a first dielectric layer, a second dielectric layer disposed on the first dielectric layer, and a third dielectric layer disposed on the second dielectric layer.

4. The test structure of claim 3, wherein the first plurality of test conductive features comprises first test conductive features disposed in the first dielectric layer, second test conductive features disposed in the second dielectric layer, and third test conductive features disposed in the third dielectric layer.

5. The test structure of claim 4, wherein the second plurality of test conductive features comprises fourth test conductive features disposed in the first dielectric layer, a fifth test conductive feature disposed in the second dielectric layer, and sixth test conductive features disposed in the third dielectric layer, wherein the fifth test conductive feature has a width that is about 3 times to about 10 times a pitch of the first test conductive features.

6. The test structure of claim 5, wherein the third plurality of test conductive features comprises a seventh test conductive feature disposed in the first dielectric layer, an eighth test conductive feature disposed in the second dielectric layer, and a ninth test conductive feature disposed in the third dielectric layer, wherein the seventh test conductive feature has a width that is about 3 times to about 10 times the pitch of the first test conductive features.

7. The test structure of claim 6, wherein the sixth test conductive features have different thicknesses.

8. The test structure of claim 6, wherein the ninth test conductive feature comprises a top portion and bottom portions extending downward from the top portion.

9. The test structure of claim 2, wherein each test conductive feature of the first, second, and third pluralities of test conductive features comprises a barrier layer and a conductive material disposed on the barrier layer.

10. A substrate, comprising:
a plurality of dies;
a plurality of scribe lines separating the plurality of dies; and
at least one test structure disposed in a scribe line of the plurality of scribe lines, the test structure comprising:
first portions arranged in a first row, wherein the first portions have decreasing thicknesses along a first direction, and each portion of the first portions comprises at least one dielectric layer and at least one test conductive feature disposed in the at least one dielectric layer.

11. The substrate of claim 10, wherein the at least one test structure further comprises second portions arranged in a second row adjacent the first portions, and each portion of the second portions comprises the at least one dielectric layer and at least one test conductive feature disposed in the at least one dielectric layer.

12. The substrate of claim 11, wherein the first portions comprise four first portions, and the second portions comprise four second portions.

13. The substrate of claim 12, wherein the at least one test conductive feature disposed in the first portions comprises a first plurality of test conductive features and a second test conductive feature, wherein the second test conductive feature has a width that is about 3 times to about 5 times a pitch of the first plurality of test conductive features.

14. The substrate of claim 13, wherein the at least one test conductive feature disposed in the second portions comprises a third test conductive feature, wherein the third test conductive feature has a width that is about 8 times to about 10 times the pitch of the first plurality of test conductive features.

15. The substrate of claim 14, wherein a portion of the second portions that includes the third test conductive feature has a thickness substantially less than a portion of the first portions that includes the second test conductive feature.

16. A method, comprising:
forming one or more dielectric layers including a test structure and a plurality of conductive features over a first substrate;
forming a dielectric layer on the one or more dielectric layers;
forming a first photoresist layer over the dielectric layer;
patterning the first photoresist layer by focusing a light on a first image plane;
transferring a pattern of the first photoresist layer to the dielectric layer;
forming conductive features in the dielectric layer;
performing a process to identify defects; and
patterning a photoresist layer disposed over a second substrate by focusing the light on a second image plane different from the first image plane using information provided by the test structure.

17. The method of claim 16, wherein the light is EUV light.

18. The method of claim 16, wherein the defects comprise first defects located over the test structure and second defects located in regions without the test structure.

19. The method of claim 18, wherein the second defects are greater than a threshold number.

20. The method of claim 18, the information provided by the test structure comprises thickness differences among portions of the test structure.
